(19) United States
(12) Patent Application Publication
(10) Pub. No.: US 2007/0290307 A1
(43) Pub. Date: Dec. 20, 2007

(54) Light emitting diode module

(75) Inventor: Feng-Li Lin, Taishan Township (TW)

Correspondence Address: BIRCH STEWART KOLASCH & BIRCH, PO BOX 747, FALLS CHURCH, VA, 22040-0747, US

(73) Assignee: Gigno Technology Co., Ltd.

(21) Appl. No.: 11/808,206

(22) Filed: Jun. 7, 2007

(30) Foreign Application Priority Data
Jun. 16, 2006 (TW) 095121785

(51) Int. Cl. H01L 23/02

(52) U.S. Cl. 257/678

(57) ABSTRACT

A light emitting diode (LED) module includes a circuit substrate and a plurality of LED dies. The circuit substrate sequentially includes a metal layer, a first dielectric layer and an interconnection layer. The first dielectric layer has a plurality of openings. The LED dies are respectively disposed in the openings and electrically connected with the interconnection layer.

### CROSS REFERENCE TO RELATED APPLICATIONS

This Non-provisional application claims priority under 35 U.S.C. §119(a) on Patent Application No(s). 095121785 filed in Taiwan, Republic of China on Jun. 16, 2006, the entire contents of which are hereby incorporated by reference.

### BACKGROUND OF THE INVENTION

1. Field of Invention

The invention relates to a light emitting module, and, in particular, to a light emitting diode (LED) module.

2. Related Art

A light emitting diode (LED) is a lighting element made of a semiconductor material. The LED has two electrode terminals. When an extremely low voltage is applied across the terminals, the redundant energy may be excited in the form of light according to the combination of electrons and holes.

Different from the typical incandescent light bulb, the LED pertains to the cold lighting elements and has the advantages including the low power consumption, the long lifetime, the needlessness of the warm-up time, and the quick response speed. Moreover, the LED has the small size, can withstand the vibration, is adapted to the mass production, and is adapted to the formation of the extremely small or array-type module according to the requirement of the application. Therefore, the LED may be widely applied to illuminating apparatuses, indicators and display devices of information, communication and consumer electronic products, and thus becomes the indispensable element in the daily life.

Referring to FIG. 1, a conventional LED module 10 includes a carrier S and a plurality of LED devices 20. Each LED device 20 is disposed on the carrier S, and the electrical connection thereof is made through the circuit on the carrier S. In addition, in order to enhance the availability of the light ray, a reflector (not shown) may be attached to a surface of the carrier S of the LED module 10 according to the prior art.

FIG. 2 is a schematically cross-sectional view along a line A-A of FIG. 1 to show the LED device. Referring to FIG. 2, the LED device 20 includes a substrate 21, an LED die 22, a leadframe 23 and a molding compound 24.

The leadframe 23 is disposed on the substrate 21. The LED die 22 is disposed over the leadframe 23 through bumps 221, and is electrically connected with an external device through the leadframe 23. The molding compound 24 encapsulates the LED die 22 to protect the LED die 22 and to form the LED device 20.

As shown in FIGS. 1 and 2, the processes of assembling the LED module 10 are very complicated because the leadframe 23 has to be combined with the substrate 21 and the bumps 221 have to be formed on the LED die 22 for electrically connecting the LED die 22 and the leadframe 23. After that, a plurality of assembled LED devices 20 has to be disposed on the carrier S so as to completely manufacture the LED module 10. In order to enhance the availability of the light ray, a reflector has to be attached to the surface of the carrier S, and the assembling time is thus lengthened.

In addition, it is an important subject to solve the heat dissipating problem of the LED die 22 or the LED device 20. After a long period of usage, the temperature of the LED device 20 may increase due to the incomplete opto-electronic conversion of the LED die 22, which generates the considerable heat. If the temperature of the LED device 20 is not decreased, the lighting efficiency of the LED die 22 may be influenced or even the lifetime thereof may be shortened. In the prior art, the heat generated by each LED die 22 only can be transferred to the carrier S through the bumps 221 and the leadframe 23 and then be dissipated. In this case, the heat dissipation requirement of the LED module 10 cannot be satisfied.

Thus, it is an important subject to provide a LED module capable of solving the problem of the heat dissipation in the LED die and the LED device.

### SUMMARY OF THE INVENTION

In view of the foregoing, the invention is to provide a LED module capable of solving the heat dissipation problem.

To achieve the above, the invention discloses a light emitting diode (LED) module including a circuit substrate and a plurality of LED dies. The circuit substrate sequentially includes a metal layer, a first dielectric layer and an interconnection layer. The first dielectric layer has a plurality of openings. The LED dies are respectively disposed in the openings and electrically connected with the interconnection layer.

To achieve the above, the invention also discloses a light emitting diode (LED) module including a circuit substrate and a plurality of LED devices. The circuit substrate sequentially includes a metal layer, a first dielectric layer and an interconnection layer. The first dielectric layer has a plurality of openings. The LED devices are respectively disposed in the openings and electrically connected with the interconnection layer.

As mentioned above, the LED module of the invention includes a plurality of LED dies and a circuit substrate, which includes a metal layer. Compared with the prior art, the LED die of the LED module may be in direct contact with the metal layer to rapidly transfer the heat generated by the LED die so as to dissipate the heat of the LED die effectively, and to lengthen the lifetime of the LED module. Accordingly, the lighting quality of the LED module may further be ensured. In addition, the LED die is disposed in the opening of the circuit substrate, and each opening may serve as the package encapsulating boundary in order to decrease and shorten the number of steps and the time in the packaging process. Furthermore, the LED dies only have to be disposed on the metal substrate to complete the assembling of the LED module, so the number of steps and the time in the assembling process are also decreased and shortened. In addition, another LED module of the invention includes a circuit substrate and a plurality of LED devices. The LED device includes a substrate and an LED die disposed on the substrate. The heat generated by the LED die may be directly transferred from the substrate to the interconnection layer or the metal layer so that the temperature of the LED device can be decreased, the lifetime of the LED module can be lengthened, and the lighting quality of the LED module can be ensured.

### BRIEF DESCRIPTION OF THE DRAWINGS

The invention will become more fully understood from the detailed description given herein below illustration only, and thus is not limitative of the present invention, and wherein:

FIG. 1 is a schematic illustration showing a conventional LED module;

FIG. 2 is a schematically cross-sectional view taken along a straight line A-A of FIG. 1 to show an LED device of the conventional LED module;

FIG. 3 is a pictorial view showing an LED module according to a first embodiment of the invention;

FIG. 4 is a schematically cross-sectional view taken along a straight line B-B of FIG. 3 to show the LED module according to the first embodiment of the invention;

FIG. 5 is a schematically cross-sectional view showing another LED module according to the first embodiment of the invention;

FIG. 6 is a schematically cross-sectional view showing still another LED module according to the first embodiment of the invention;

FIG. 7 is a schematically cross-sectional view showing yet still another LED module according to the first embodiment of the invention;

FIG. 8 is a schematically cross-sectional view showing yet still another LED module according to the first embodiment of the invention;

FIG. 9 is a schematically cross-sectional view showing yet still another LED module according to the first embodiment of the invention;

FIG. 10 is a schematically cross-sectional view showing yet still another LED module according to the first embodiment of the invention;

FIG. 11 is a schematic illustration showing an LED module according to a second embodiment of the invention;

FIG. 12 is a schematically cross-sectional view taken along a straight line B-B of FIG. 11 to show the LED module according to the second embodiment of the invention;

FIG. 13 is a schematically cross-sectional view showing another LED module according to the second embodiment of the invention;

FIG. 14 is a schematically cross-sectional view showing still another LED module according to the second embodiment of the invention;

FIG. 15 is a schematically cross-sectional view showing yet still another LED module according to the second embodiment of the invention; and

FIG. 16 is another pictorial view showing the LED module according to the second embodiment of the invention.

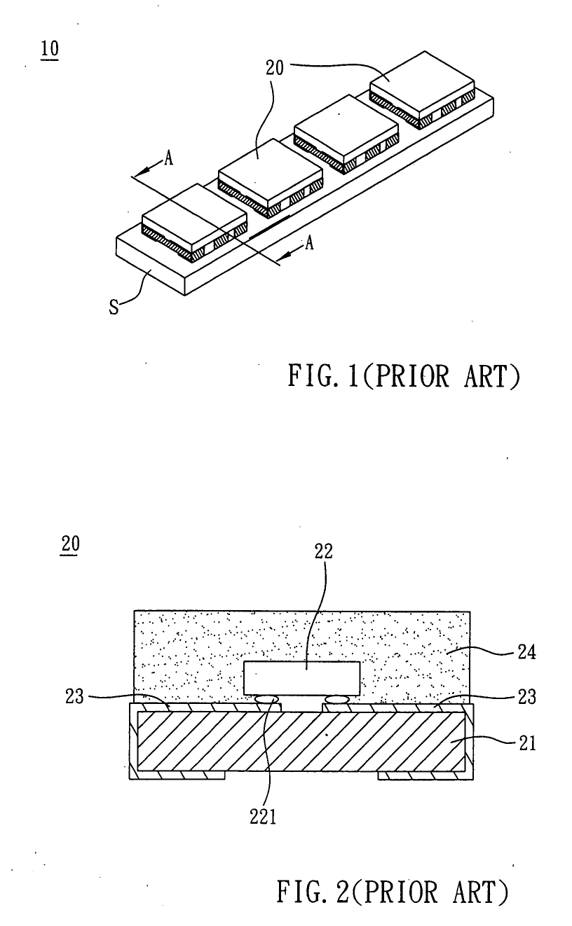

### DETAILED DESCRIPTION OF THE INVENTION

The present invention will be apparent from the following detailed description, which proceeds with reference to the accompanying drawings, wherein the same references relate to the same elements.

### First Embodiment

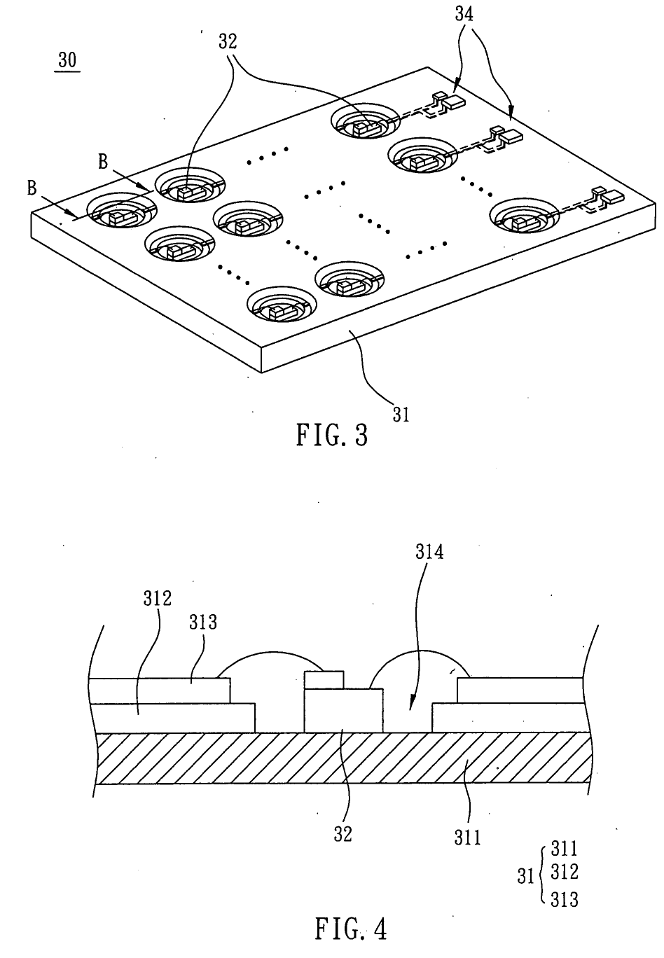

An LED module 30 according to a first embodiment of the invention will be described with reference to FIGS. 3 to 10.

Referring to FIG. 3, the LED module 30 includes a circuit substrate 31 and a plurality of LED dies 32. It is to be noted that the number and the arrangement of the LED dies 32 of the LED module 30 are not particularly restricted. In this embodiment, the LED dies 32 are arranged in an array. Of course, the LED dies 32 may be arranged along a straight line.

Please refer to FIGS. 3 and 4 simultaneously, wherein FIG. 4 is a schematically cross-sectional view taken along a straight line B-B of FIG. 3 to illustrate the connection relationship between each of the LED dies 32 and the circuit substrate 31. The circuit substrate 31 sequentially includes a metal layer 311, a first dielectric layer 312 and an interconnection layer 313. For example, the circuit substrate 31 can be a printed circuit board (PCB), such as a flexible PCB or a rigid PCB. The first dielectric layer 312 disposed between the metal layer 311 and the interconnection layer 313 serves as an insulating layer. The material of the metal layer 311 may be a metal, such as copper or aluminum, having high thermal conductivity. The thickness of the metal layer 311 may reach several micrometers (μm). In the embodiment, the metal layer 311 can be a composite laminate layer, which is composed of several stacked metal layers. For example, the composite laminate layer may include a copper layer and an aluminum layer stacked on the copper layer. In addition, the first dielectric layer 312 has a plurality of openings 314 to expose the metal layer 311.

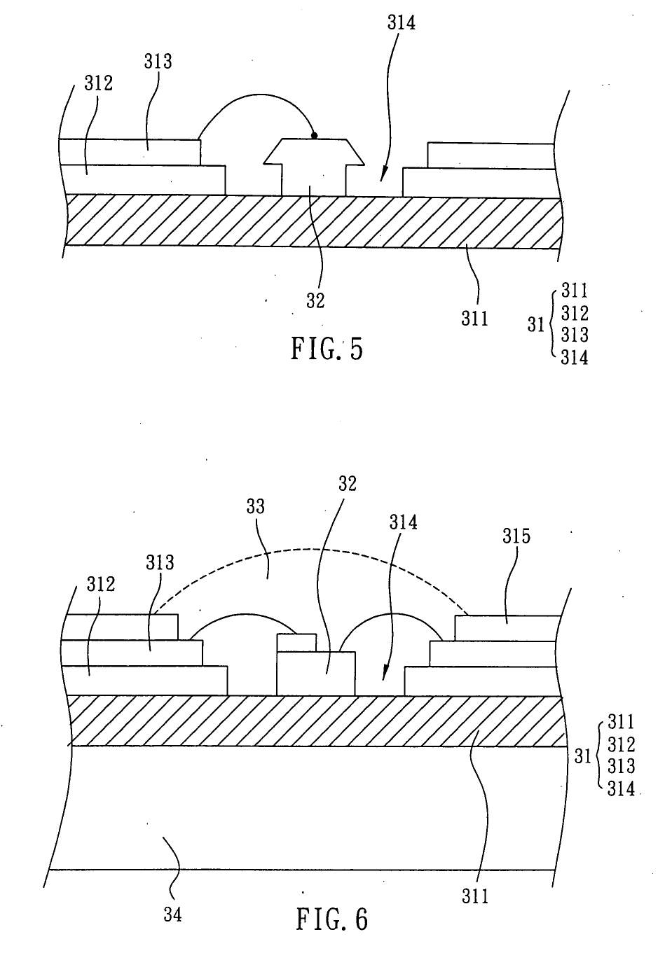

The LED dies 32 are respectively disposed in the openings 314 and are electrically connected with the interconnection layer 313 to form the so-called “chip on board (COB)” structure. Each LED die 32 can be controlled and driven through the connection of the interconnection layer 313. In this embodiment, the type of the LED die 32 is not particularly restricted. In the example of FIG. 4, the LED die 32 has electrodes formed on the same surface. Two wires have to be bonded to the LED die 32 and the interconnection layer 313 so that the LED die 32 can be electrically connected with the interconnection layer 313. Of course, the electrodes of the LED die 32 may be formed on different sides to form a vertical connecting die (see FIG. 5). The LED die 32 may be electrically connected with the interconnection layer 313 by way of wire bonding or flip chip bonding according to the types of the LED dies 32.

Referring to FIG. 6, the circuit substrate 31 of this embodiment may further include a second dielectric layer 315 disposed on the interconnection layer 313, and the openings 314 are exposed from the second dielectric layer 315. The second dielectric layer 315 is a highly reflective layer, and the material thereof may be a mixture of titanium dioxide (TiO2) and resin. A white surface with the high reflectivity may be formed on the circuit substrate 31 using the mixture of the titanium dioxide and the resin. Consequently, the light ray outputted from the LED die 32 may have better light ray availability. If the circuit substrate 31 is a PCB, the second dielectric layer 315 can be an insulating layer additionally formed on a surface of the PCB.

In addition, the LED module 30 may further include a molding compound 33 filled into the opening 314 exposed from the second dielectric layer 315 with an edge of the opening 314 serving as a package encapsulating boundary. Consequently, no recess has to be formed to serve as the package encapsulating boundary, and the number of steps and the time for the packaging process may be respectively decreased and shortened. In addition, the molding compound 33 may be a lens or any other light-permeable covering material capable of decorating the light shape of the LED die 32.

Referring to FIG. 6 again, the LED module 30 may further include a thermal conductive metal board 34 connected with the metal layer 311 by way of attaching, adhering or fastening. Consequently, the total thickness of the metal portion in the circuit substrate 31 can be increased to help dissipating heat.

Because each LED die 32 is in direct contact with the metal layer 311, the heat generated by the LED die 32 can be directly transferred out through the metal layer 311. Thus, the heat dissipation of the LED die 32 can be effectively enhanced, the lifetime of the LED die 32 can be lengthened, and the lighting quality of the LED die 32 can be enhanced. In addition, the LED dies 32 of the invention only have to be disposed on the circuit substrate 31 to complete the assembling of the LED module 30, so the number of steps and the time can be respectively decreased and shortened.

Referring to FIG. 3, the LED module 30 may further include a driving circuit 34 disposed on the circuit substrate 31 and electrically connected with each LED die 32 to drive the LED dies 32. The driving circuit 34 may include an active device or a passive device. The active device may be a switch element, such as a transistor or a diode. The passive device may be a capacitor, a resistor, an inductor or any combination thereof. In this embodiment, the LED module 30 includes a plurality of driving circuits 34.

It is to be noted that the structure of the circuit substrate 31 may still have different aspects in this embodiment.

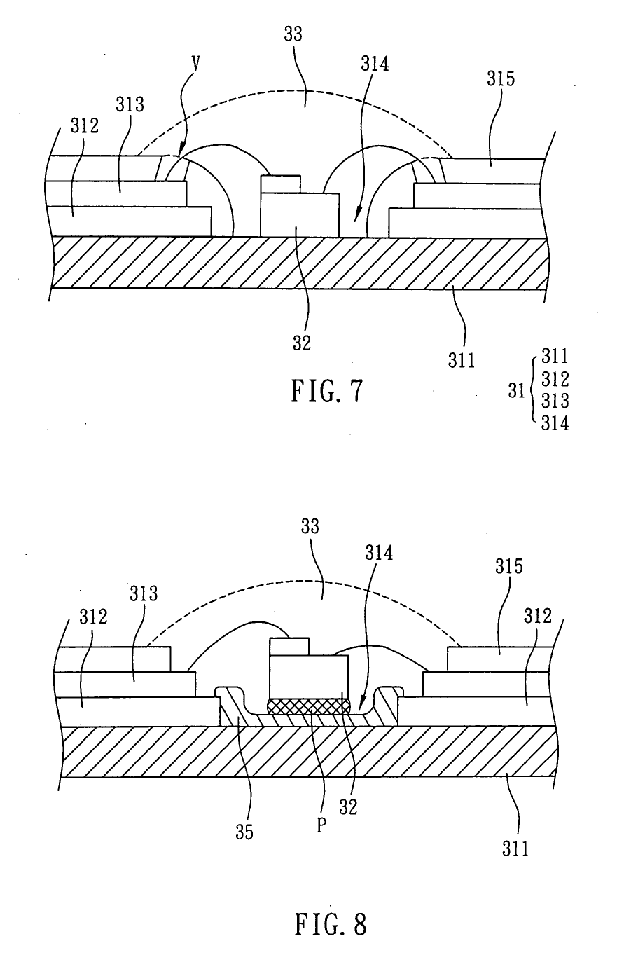

As shown in FIG. 7, the second dielectric layer 315 may also extend to the edge of the opening 314, and the LED die 32 passes through the second dielectric layer 315 and is electrically connected with the interconnection layer 313. In the actual manufacturing process, a through hole V for wire bonding may be left in the second dielectric layer 315 to facilitate the wire bonding process.

Referring to FIGS. 3 and 8, the circuit substrate 31 may further include a plurality of metal pad layers 35 respectively filled into the openings 314. More particularly, the metal pad layer 35 may further extend from the opening 314 to the edge of the first dielectric layer 312, or even to the edge of the interconnection layer 313 and thus be connected with the pattern of a portion of the interconnection layer 313. The LED dies 32 are respectively disposed on the metal pad layers 35. The metal pad layer 35 may be in direct contact with the LED die 32 in order to increase the height of the LED die 32 and to prevent the light ray outputted from the side surface of the LED die 32 from being shielded by the first dielectric layer 312 and the second dielectric layer 315. In addition, the metal, such as silver, having high reflectivity may be plated on the surface of the metal pad layer 35 so that the lateral light outputted from the LED die 32 may be reflected upwards and the light availability can thus be enhanced. In addition, the metal pad layer 35 can further assist in the heat transfer. The LED die 32 may be applied with the soldering paste P and then disposed on the metal pad layer 35 so that the connection strength between the LED die 32 and the metal pad layer 35 may be enhanced.

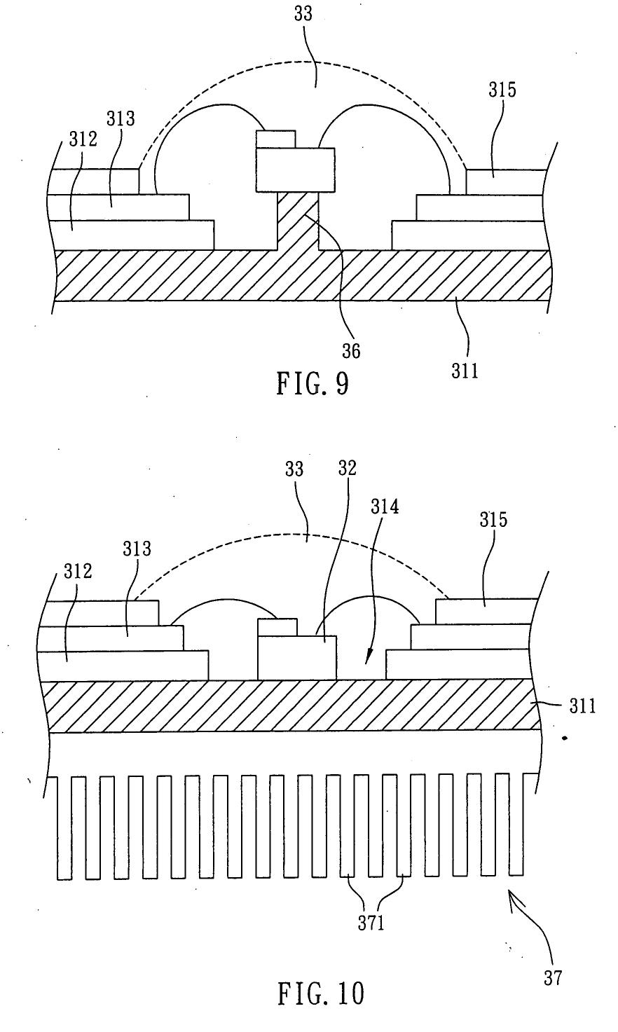

As shown in FIG. 9, the metal pad layer 35 and the metal layer 311 may also be integrally formed. That is, an embossment 36 may extend from the metal layer 311 into the opening 314. The embossment 36 may be a metal sheet, a soldering paste or a combination thereof. For example, one or two sides of the metal sheet may be applied with the soldering paste and then the metal sheet is disposed in the opening 314. The height of the embossment 36 may be freely adjusted to facilitate the electrical connection between the LED die 32 and the interconnection layer 313.

As shown in FIG. 10, the LED die 32 directly contacts the metal layer 311 to assist in the heat dissipation. In order to enhance the heat dissipation efficiency, a heat dissipation device 37 may be attached to the LED module 30, as shown in FIG. 10. The heat dissipation device 37 is connected to the metal layer 311 by way of attaching, adhering and fastening, for example, so that the heat dissipation device 37 can be connected to the metal layer 311. The heat dissipation device 37 may have a plurality of heat dissipating fins 371 (as shown in FIG. 10) or have any other heat dissipating assembly such as a heat pipe or a fan.

### Second Embodiment

An LED module 40 according to a second embodiment of the invention will be described with reference to FIGS. 11 to 16.

Referring to FIG. 11, the LED module 40 includes a circuit substrate 41 and a plurality of LED devices 42. The technological feature and effect of the circuit substrate 41 are the same as those of the circuit substrate 31 of the first embodiment, so detailed descriptions thereof will be omitted.

The LED module 40 may further include a driver circuit 44 disposed on the circuit substrate 41 and electrically connected with each LED device 42 to drive the LED devices 42. The technological feature and effect of the driver circuit 44 are the same as those of the driver circuit 34 of the first embodiment, so detailed descriptions thereof will be omitted.

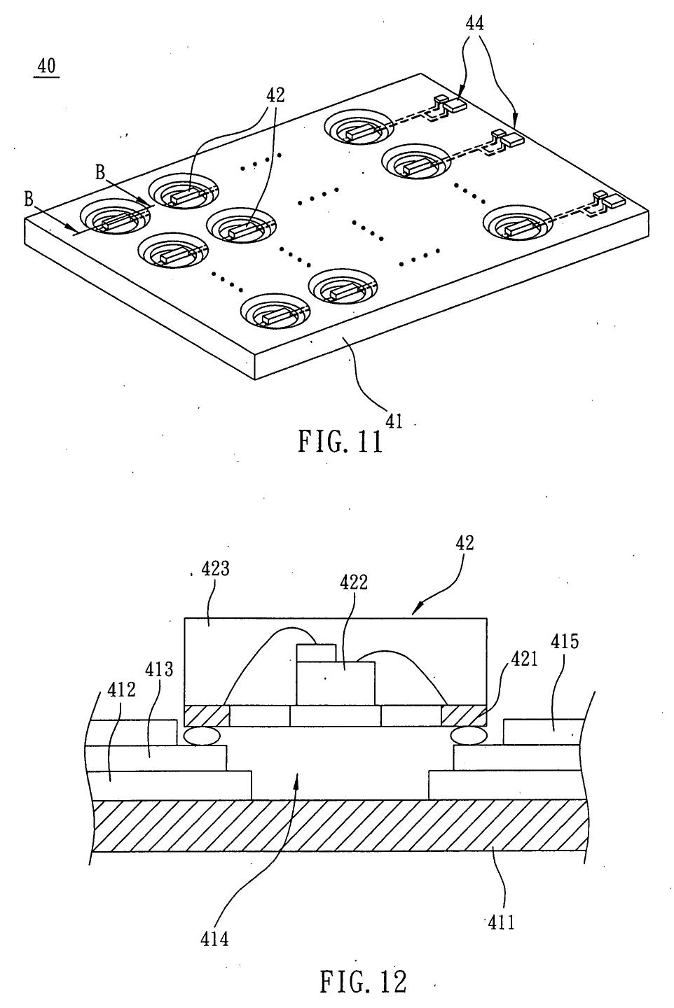

Referring to FIGS. 11 and 12 simultaneously, the second embodiment is different from the first embodiment mainly in that the LED device 42, instead of a necked die, is accommodated in an opening 414 of the circuit substrate 41 in the second embodiment. The LED device 42 includes a substrate 421, a LED die 422 and a molding compound 423. The LED die 422 is disposed on the substrate 421, which may be a leadframe, a ceramics substrate or a metal substrate. Of course, the ceramics substrate may also be embedded with metal (see the hatched portion) by way of printing or any other method so that the metal is electrically connected with the electrode of the LED die 422. In addition, the molding compound 423 encapsulates the LED die 422. The technology feature and effect of the molding compound 423 are the same as those of the molding compound 33 of the first embodiment, so detailed descriptions thereof will be omitted. In the example of FIG. 12, the substrate 421 is a metal substrate, and the LED device 42 may be electrically connected with an interconnection layer 413 by way of surface mount technology (SMT).

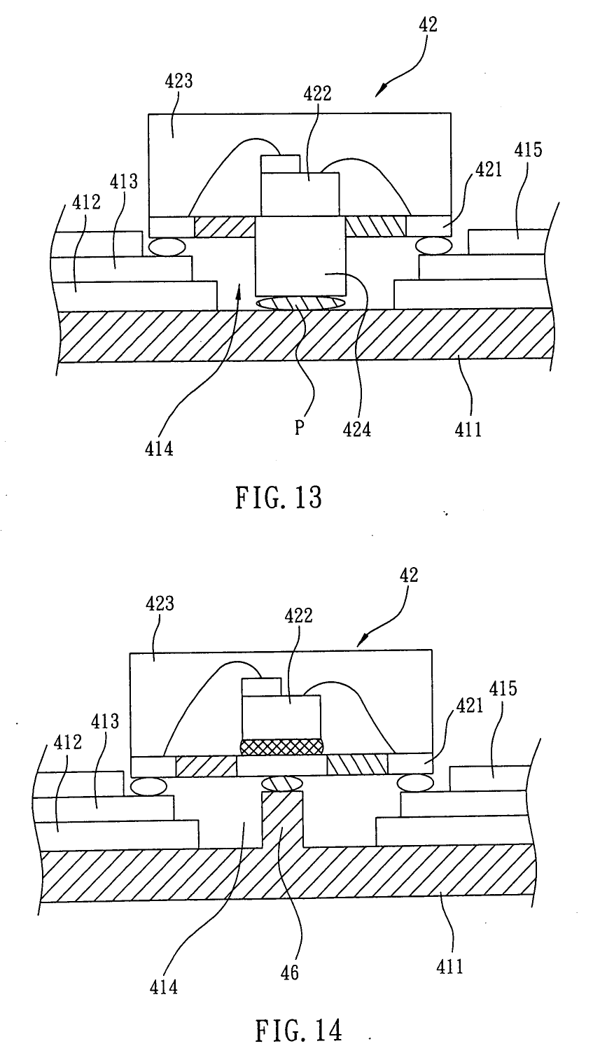

In addition, in order to make the heat generated by the LED die 422 be directly and rapidly transferred to a metal layer 411, a protrusion 424 extends from the substrate 421 of the LED device 42, as shown in FIG. 13. The protrusion 424 is connected with the metal layer 411. For example, the substrate 421 may be applied with the soldering paste P at the protrusion 424 and then connected with the metal layer 411.

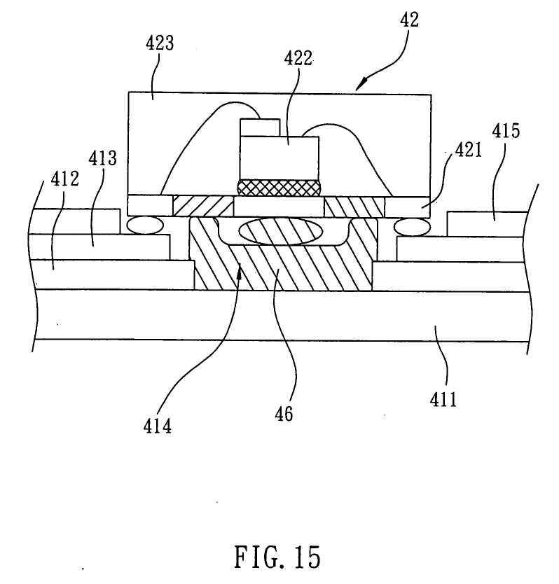

In order to enhance the heat dissipation efficiency, an embossment 46 may extend to the opening 414 of the metal layer 411. As shown in FIGS. 14 and 15, the metal layer 411 has the embossment 46, which may be a metal sheet, a metal washer, a soldering paste or the combination thereof. The technological feature of the metal washer are the same as that of the metal pad layer 35 of the first embodiment, so detailed descriptions thereof will be omitted.

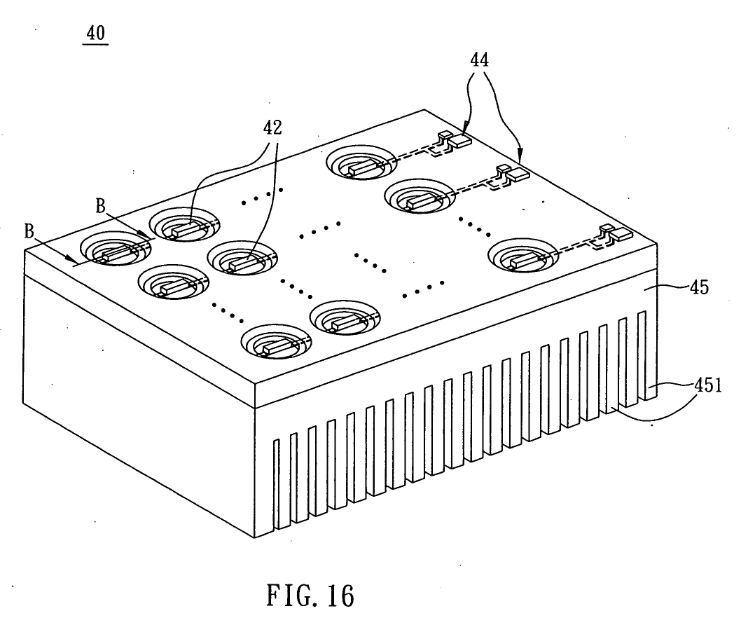

As shown in FIG. 16, the LED module 40 may further include a heat dissipation device 45, which has a plurality of heat dissipating fins 451. The heat dissipation device 45 is connected to the metal layer 411 by way of attaching, adhering or fastening.

In summary, the LED module of the invention includes a plurality of LED dies and a circuit substrate, which includes a metal layer. Compared with the prior art, the LED die of the LED module may be in direct contact with the metal layer to rapidly transfer the heat generated by the LED die so as to dissipate the heat of the LED die effectively, and to lengthen the lifetime of the LED module. Accordingly, the lighting quality of the LED module may further be ensured. In addition, the LED die is disposed in the opening of the circuit substrate, and each opening may serve as the package encapsulating boundary in order to decrease and shorten the number of steps and the time in the packaging process. Furthermore, the LED dies only have to be disposed on the metal substrate to complete the assembling of the LED module, so the number of steps and the time in the assembling process are also decreased and shortened. In addition, another LED module of the invention includes a circuit substrate and a plurality of LED devices. The LED device includes a substrate and an LED die disposed on the substrate. The heat generated by the LED die may be directly transferred from the substrate to the interconnection layer or the metal layer so that the temperature of the LED device can be decreased, the lifetime of the LED module can be lengthened, and the lighting quality of the LED module can be ensured.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light emitting diode (LED) module, comprising:
a circuit substrate sequentially comprising a metal layer, a first dielectric layer and an interconnection layer, wherein the first dielectric layer has a plurality of openings; and
a plurality of LED dies respectively disposed in the openings, wherein the LED dies are electrically connected with the interconnection layer.

2. The LED module according to claim 1, wherein the metal layer is a composite laminate layer.

3. The LED module according to claim 1, further comprising:
a thermal conductive metal board connected with the metal layer.

4. The LED module according to claim 3, further comprising:
a heat dissipation device connected with the thermal conductive metal board.

5. The LED module according to claim 1, wherein the circuit substrate further comprises a second dielectric layer disposed on the interconnection layer, and the opening is exposed from the second dielectric layer.

6. The LED module according to claim 5, wherein a material of the second dielectric layer is a mixture of titanium dioxide and resin.

7. The LED module according to claim 5, further comprising:
a molding compound filled in the opening exposed from the second dielectric layer with an edge of the second dielectric layer serving as a package molding boundary.

8. The LED module according to claim 5, wherein the second dielectric layer extends from an edge of the opening, and the LED dies pass through the second dielectric layer and are thus electrically connected with the interconnection layer.

9. The LED module according to claim 1, wherein the metal layer is formed with embossments respectively disposed in the openings.

10. The LED module according to claim 1, wherein the circuit substrate further comprises a plurality of metal pad layers respectively filled into the openings, and the LED dies are respectively disposed on the metal pad layers.

11. The LED module according to claim 10, wherein the metal pad layers respectively extend from the openings to an edge of the first dielectric layer.

12. The LED module according to claim 1, further comprising:
a driving circuit disposed on the circuit substrate and electrically connected with the LED dies.

13. A light emitting diode (LED) module, comprising:
a circuit substrate sequentially comprising a metal layer, a first dielectric layer and an interconnection layer, wherein the first dielectric layer has a plurality of openings; and
a plurality of LED devices respectively disposed in the openings, wherein the LED devices are electrically connected with the interconnection layer.

14. The LED module according to claim 13, wherein the metal layer is a composite laminate layer.

15. The LED module according to claim 13, further comprising:
a thermal conductive metal board connected with the metal layer.

16. The LED module according to claim 15, further comprising:
a heat dissipation device connected with the thermal conductive metal board.

17. The LED module according to claim 13, wherein each of the LED devices comprises a substrate, an LED die disposed on the substrate and a molding compound encapsulating the LED die.

18. The LED module according to claim 17, wherein the substrate is a leadframe, a ceramics substrate or a metal substrate.

19. The LED module according to claim 17, wherein the substrate has a protrusion connected with the metal layer.

20. The LED module according to claim 13, wherein the circuit substrate further comprises a second dielectric layer disposed on the interconnection layer, and the opening is exposed from the second dielectric layer.

21. The LED module according to claim 20, wherein a material of the second dielectric layer is a mixture of titanium dioxide and resin.

22. The LED module according to claim 13, wherein the metal layer is formed with embossments respectively disposed in the openings.

23. The LED module according to claim 17, further comprising:
a driving circuit disposed on the circuit substrate and electrically connected with the LED devices.
